(19) United States
(12) Patent Application Publication
(10) Pub. No.: US 2012/0098010 A1
(43) Pub. Date: Apr. 26, 2012

(54) LIGHT EMITTING ELEMENT PACKAGE

(75) Inventors: SHIUN-WEI CHAN, Hukou (TW); CHIH-HSUN KE, Hukou (TW)

(73) Assignee: ADVANCED OPTOELECTRONIC TECHNOLOGY, INC., Hsinchu Hsien (TW)

(21) Appl. No.: 13/237,910

(22) Filed: Sep. 20, 2011

(30) Foreign Application Priority Data
Oct. 20, 2010 (CN) 201010513621.1

(51) Int. Cl. H01L 33/50; H01L 33/42; B82Y 99/00

(52) U.S. Cl. 257/98; 977/742; 257/E33.061; 257/E33.064

(57) ABSTRACT

A light emitting element package includes a substrate, a light emitting element, and a package member. The substrate includes a first solder pad and a second solder pad. The light emitting element is mounted on the substrate and includes a p-type electrode and an n-type electrode. The package member is configured for enveloping the light emitting element. A first electrode and a second electrode are formed on the package member. The first electrode and the second electrode of the package member are electrically coupled to the p-type electrode and the n-type electrode of the light emitting element. The first electrode and the second electrode of the package member are electrically coupled to the first solder pad and the second solder pad of the substrate.

### BACKGROUND

1. Technical Field

The disclosure relates generally to semi-conductive devices, and more particularly to a light emitting element package.

2. Description of the Related Art

In the light emitting element package, gold wires are utilized to electrically couple the electrodes of the light emitting element on the substrate to exterior electrodes. However, the gold wires are not cost-effective and not easily bonded to the substrate.

Therefore, there is a need for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout two views.

FIG. 1 is a cross sectional view of a light emitting element package in accordance with a first embodiment of the disclosure.

FIG. 2 is a cross sectional view of a light emitting element package in accordance with a second embodiment of the disclosure.

### DETAILED DESCRIPTION

The disclosure is illustrated by way of example and not by way of limitation in the figures of the accompanying drawings. It should be noted that references to “an” or “one” embodiment in this disclosure are not necessarily to the same embodiment, and such references mean at least one.

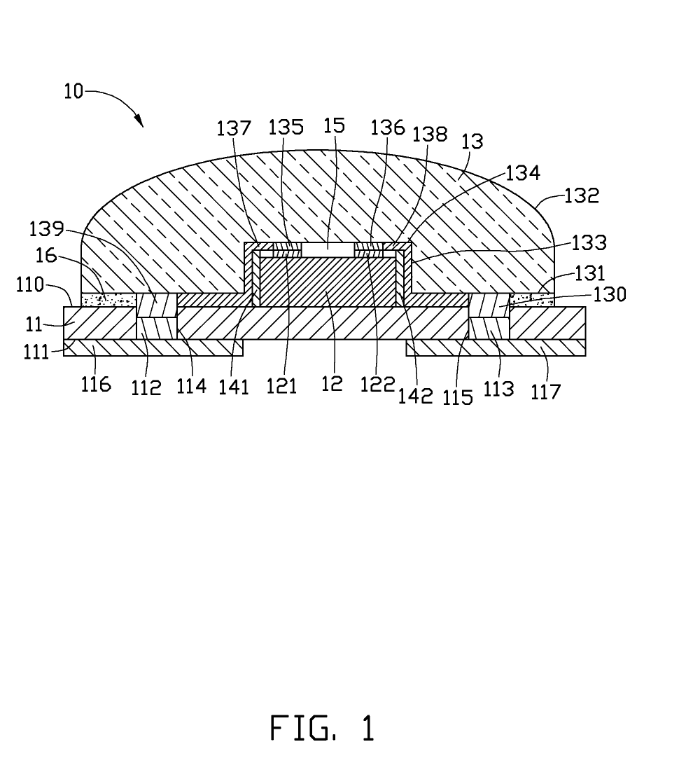

Referring to FIG. 1, a light emitting element package 10 in accordance with a first embodiment of the disclosure includes a substrate 11, a light emitting element 12 and a package member 13.

The substrate 11 is made of electrically insulating material. The substrate 11 includes a first surface 110 and a second surface 111 opposite to the first surface 110. A first position hole 114 and a second position hole 115 are defined in the substrate 11. The first position hole 114 and the second position hole 115 are through holes. A first solder pad 116 and a second solder pad 117 are formed on the second surface 111 respectively aligned with the first position hole 114 and the second position hole 115.

The light emitting element 12 includes a p-type electrode 121 and an n-type electrode 122. The p-type electrode 121 and the n-type electrode 122 are formed the same side of the light emitting element 12. In the embodiment, the p-type electrode 121 and the n-type electrode 122 are formed at the upper side of the light emitting element 12. The light emitting element 12 is mounted on the first surface 110.

The package member 13 is made of transparent or semi-transparent materials. The package member 13 includes a mounting surface 131 and a light emitting surface 132. The light emitting surface 132 is smooth and curved. A plurality of phosphor materials can be mixed in the package member 13 or formed on the light emitting surface 132.

The mounting surface 131 is planar and defined at the bottom of the package member 13. A receiving portion 133 is defined in the mounting surface 131. A light incident surface 134 is defined at the receiving portion 133. A first electrode 135, a second electrode 136, a first transparent conductive layer 137, a second transparent conductive layer 138, a first conductive protrusion 139, and a second conductive protrusion 130 are provided at the bottom of the package member 13. The first electrode 135 and a second electrode 136 are formed at the light incident surface 134. The first conductive protrusion 139 and the second conductive protrusion 130 are formed at the mounting surface 131. The first transparent conductive layer 137 connects the first electrode 135 to the first conductive protrusion 139. The second transparent conductive layer 138 connects the second electrode 136 to the second conductive protrusion 130. The first transparent conductive layer 137 and the second transparent conductive layer 138 can be made of transparent metal, indium tin oxide (ITO) or carbon nanotubes. The first transparent conductive layer 137 and the second transparent conductive layer 138 are formed on the package member 13 by electroplating, evaporation, sputtering, or electron beam deposition.

The mounting surface 131 of the package member 13 is mounted on the first surface 110 of the substrate 11. The first conductive protrusion 139 and the second conductive protrusion 130 are respectively received in the first position hole 114 and the second position hole 115. In this embodiment, a sealing material 16 is located between the mounting surface 131 and the first surface 110. A plurality of conductive materials is filled in the first position hole 114 and the second position hole 115 for forming a first conductive pin 112 and a second conductive pin 113. The first conductive protrusion 139 is electrically coupled to the first solder pad 116 through the first conductive pin 112. The second conductive protrusion 130 is electrically coupled to the second solder pad 117 through the second conductive pin 113.

The light emitting element 12 is mounted in the receiving portion 133. The p-type electrode 121 and the n-type electrode 122 face the package member 13. A cavity 15 is defined among the light emitting element 12, the package member 13, the first and second electrodes 135, 136 and the p-type and n-type electrodes 121, 122. The first electrode 135 is electrically coupled to the p-type electrode 121 by eutectic bonding. The second electrode 136 is electrically coupled to the n-type electrode 122 by eutectic bonding.

In this embodiment, a first electrically insulating layer 141 is defined between the first transparent conductive layer 137 and the light emitting element 12. A second electrically insulating layer 142 is defined between the second transparent conductive layer 138 and the light emitting element 12.

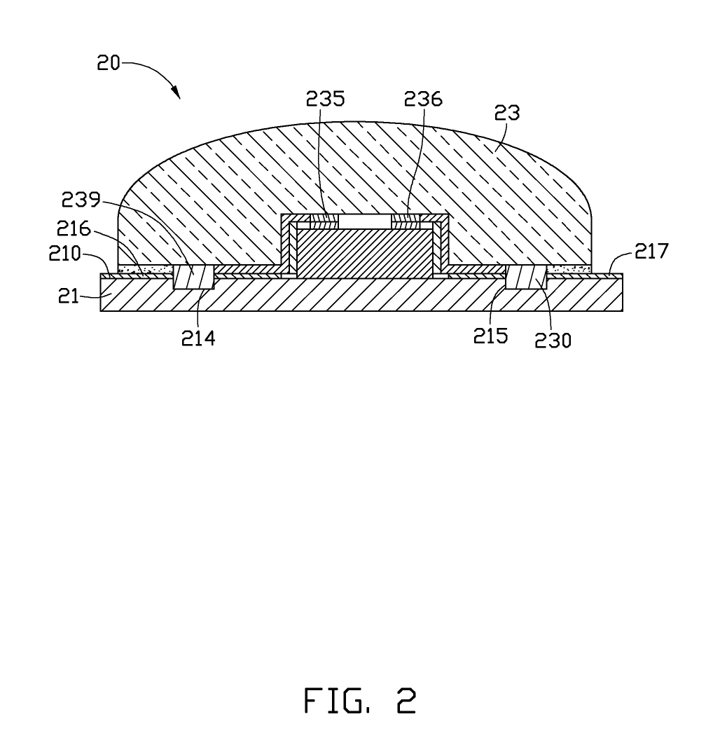

Referring to FIG. 2, a light emitting element package 20 in accordance with a second embodiment of the disclosure is similar to the light emitting element package 10, differing only in that a first position hole 214 and a second position hole 215 are blind holes. The first position hole 214 and the second position hole 215 are defined in the first surface 210 of the substrate 21. A first solder pad 216 and a second solder pad 217 are formed on the first surface 210 of the substrate 21, wherein the first solder pad 216 surrounds the first position hole 214 and the second solder pad 217 surrounds the second position hole 215. A first conductive protrusion 239 is received in the first position hole 214 of the substrate 21. A second conductive protrusion 230 is received in the second position hole 215 of the substrate 21. The first conductive protrusion 239 is connected to the first solder pad 216. The second conductive protrusion 230 is connected to the second solder pad 217. Therefore, the first electrode 235 is electrically coupled to the first solder pad 216 of the substrate 21. The second electrode 236 is electrically coupled to the second solder pad 217 of the substrate 21.

While the disclosure has been described by way of example and in terms of exemplary embodiment, it is to be understood that the disclosure is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light emitting element package comprising:
a substrate comprising a first solder pad and a second solder pad;
a light emitting element mounted on the substrate and comprising a p-type electrode and a n-type electrode; and
a package member enveloping the light emitting element, a first electrode and a second electrode formed on the package member, the first electrode and the second electrode of the package member respectively aligned with the p-type electrode and the n-type electrode of the light emitting element, and the first electrode of the package member electrically coupled to the p-type electrode of the light emitting element, and the second electrode electrically coupled to the n-type electrode of the light emitting element, the first electrode and the second electrode of the package member respectively electrically coupled to the first solder pad and the second solder pad of the substrate.

2. The light emitting element package of claim 1, wherein the package member further comprising a mounting surface and a light emitting surface, a receiving portion is defined in the mounting surface of the package member and receives the light emitting element therein, a light incident surface is defined in the receiving portion of the package member, the first electrode and the second electrode of the package member are formed on the incident surface of the package member.

3. The light emitting element package of claim 1, wherein the first electrode of the package member and the p-type electrode of the light emitting element are electrically coupled by eutectic bounding, and the second electrode of the package member and the n-type electrode of the light emitting element are electrically coupled by eutectic bounding.

4. The light emitting element package of claim 1, wherein a first conductive protrusion and a second conductive protrusion are formed on the mounting surface of the package member, a first position hole and a second position hole are defined in the substrate, the first conductive protrusion is received in the first position hole and the second conductive protrusion is received in the second position hole, the first conductive protrusion is electrically coupled to the first electrode of the package member and the first solder pad of the substrate, the second conductive protrusion is electrically coupled to the second electrode of the package member and the second solder pad of the substrate.

5. The light emitting element package of claim 4, wherein the first conductive protrusion of the package member is electrically coupled to the first electrode of the package member through a first transparent conductive layer and the second conductive protrusion of the package member is electrically coupled to the second electrode of the package member through a second transparent conductive layer.

6. The light emitting element package of claim 5, wherein the first transparent conductive layer and the second transparent conductive layer are selected from a group consisting of transparent metal, indum tin oxide, and carbon nanotubes.

7. The light emitting element package of claim 5, wherein a first insulation layer is formed between the first transparent conductive layer and the light emitting element, and a second insulation layer is formed between the second transparent conductive layer and the light emitting element.

8. The light emitting element package of claim 4, wherein a first conductive pin and a second conductive pin are respectively defined in the first position hole and the second position hole by filling conductive materials in the first and second position holes, the first conductive protrusion is electrically coupled to the first solder pad through the first conductive pin, and the second conductive protrusion is electrically coupled to the second solder pad through the second conductive pin.

9. The light emitting element package of claim 1 further comprising phosphor materials, the phosphor material is mixed in the package member or is coated on the light emitting surface of the package surface.

10. The light emitting element package of claim 1, wherein the p-type electrode and n-type electrode of the light emitting element are formed on an upper side of the light emitting element.

11. The light emitting element package of claim 4, wherein the first position hole and the second position hole are through holes.

12. The light emitting element package of claim 4, wherein the first position hole and the second position hole are blind holes.
